(19) United States
(12) Patent Application Publication
(10) Pub. No.: US 2011/0207392 A1
(43) Pub. Date: Aug. 25, 2011

(54) METHOD FOR REGULATING THE COOLING AIR IN EQUIPMENT CABINETS AND SENSOR ARRANGEMENT

(75) Inventors: Heiko Ebermann, Dresden (DE); Peter Koch, Issing (DE); Rupert Reiter, Dietersburg (DE); Wolfgang Trepte, Zehren (DE)

(73) Assignee: KNURR AG, Arnstorf (DE)

(21) Appl. No.: 13/126,113

(22) PCT Filed: Nov. 9, 2009
(86) PCT No.: PCT/EP09/07995

§ 371 Date: Apr. 26, 2011

(30) Foreign Application Priority Data
Nov. 14, 2008 (EP) PCT/EP2008/009670

(51) Int. Cl. H05K 5/00

(52) U.S. Cl. 454/184

(57) ABSTRACT

In order to improve the energy balance for air cooling in equipment cabinets, in particular cabinet arrangements in computer centres and server rooms, regulation of the fans for the cooling air circuit is proposed, by means of which precisely the required amount of cooling air can be made available in the induction area to the electronic module units, in particular servers, in the equipment cabinets.

According to the invention, at least one leakage air flow is formed between a cold air channel and an exhaust air channel, and is provided with a temperature sensor. The temperature measurement indirectly measures the flow direction and acts as a reference variable for regulating the rotation speed of the fans which, in particular, are arranged in the exhaust air channel. Regulation of the fan rotation speed matches the volume flow of the cooling air circuit to the volume flow actually required by the electronic module units, and therefore reduces the electricity consumption.

The invention relates to a method for regulating the cooling air in equipment cabinets, in particular in computer rooms, according to the introductory clause of claim 1 and to a sensor arrangement for regulating the cooling air in equipment cabinets of computer rooms according to the introductory clause of claim 10.

The invention is suitable in particular for server cabinets of server rooms or computer centres in which a plurality of cabinets are arranged.

The increasing power of process computers and servers is associated with an ever-growing heat load in the computer centres. The electronic module units or structural elements, in particular high performance processors and servers in a compact structural form, exhibit considerable power dissipation which must be removed. Conveying the air flow required to cool the electronic module units consumes a considerable portion of the electrical energy which is necessary to operate the whole system. The electrical power consumption of the fans increases proportionately to the cube of the required volume flow. A high volume flow is thus associated with a very high power consumption.

In order to keep the quantity of air to be circulated in equipment cabinets, for example server cabinets of computer rooms, as low as possible in each operating state it is known to carry out a strict separation of the cold or cooling air from the hot air or exhaust air loaded with the heat loss of the electronic module units. The strict separation of the cooling air to be fed to the electronic module units in a cabinet from the heated exhaust air to be removed prevents a mixing of the cooling air and exhaust air and thus an increased air requirement to remove the heat loss. Mixed air reduces the temperature difference of the air available for the material/heat transport and thus reduces the transported heat quantity per volume unit.

For an energy efficient cooling of electronic module units, in particular servers, in equipment cabinets it is known to use speed-regulated fans for a closed cooling air circuit (EP 1 614 333 B1).

Methods are known from air conditioning technology, wherein the pressure difference between a hot and cold side is used as a reference variable of a regulation for an air volume flow by means of variable fan rotation speeds. These methods are, however, relatively expensive and relatively imprecise with higher flow speeds and turbulent flows.

It is an object of the invention to create a method and a sensor arrangement for cooling air regulation in equipment cabinets, in particular of computer rooms, which guarantees regulation which is as accurate as possible of an air quantity to be circulated which is as low as possible and thereby a considerable energy saving.

Having regard to the method the object is achieved through the features of claim 1 and having regard to the sensor arrangement through the features of claim 10. Useful embodiments are contained in the dependent claims and in the description of the drawings.

A core idea of the inventive regulating concept for air cooled cabinets in computer centres can be seen in controlling the fans in such a way that precisely the required quantity of cooling air is made available to the electronic module units, for example servers, in their induction area. If the air quantity is too low the required removal of the heat loss of the servers is not guaranteed and overheating arises. If the air quantity is too great, too much energy is consumed and this is disadvantageous both having regard to the operating costs and to the environment.

In the inventive method and the sensor arrangement the required conveyed air volume flow for cooling a cabinet is adapted to the cooling air volume flow of the electronic module units which are predominantly servers. The necessary volume flow for the servers is thereby essentially predefined through the construction of the servers.

In a method for cooling air regulation in equipment cabinets, particularly of computer rooms, wherein cooling air is fed in a closed cooling air circuit to the electronic module units arranged in the equipment cabinets, for example servers, and the exhaust air impacted with the heat loss of the servers is cooled in an air/fluid heat exchanger, whereby the heat loss is taken up by a cooling fluid and given off outside of the computer room and the required cooling air quantity of the closed cooling air circuit is conveyed via the rotation speed regulation of fans in dependence upon the temperature of the cooling air, it is provided according to the invention to adapt the required cooling air quantity to the volume flow conveyed by ventilators of the electronic module units and to measure the temperature of the cooling air fed to the servers in a leakage air flow.

According to the invention the leakage air flow is formed between the cooling air region, for example a cooling air channel of an equipment cabinet or a cabinet arrangement with at least one equipment cabinet and a cooling unit, wherein a cold air channel is preferably formed in the cooling unit, and the exhaust air region, for example an exhaust air channel of the equipment cabinet or a hot air channel of a cooling unit, which is arranged in particular laterally abutting an equipment cabinet or between two equipment cabinets, and the temperature of the leakage air flow is measured and used as a reference variable for the rotation speed regulation of the fans.

The regulating concept or measurement principle comprises the temperature measurement of at least one leakage air flow between the cold and hot region of a cabinet, wherein the measured temperature is used to regulate the fans for the cooling air flow circuit.

It is advantageous for the formation of a leakage air flow in a cabinet or in a cabinet arrangement with at least one equipment cabinet and a cooling unit for an opening to be purposefully incorporated into the air separation, for example into an air separating wall which partitions off the cooling air channel from the exhaust air region. A temperature sensor is inserted in or also through this opening, via which the fans which are arranged for example in a rear side exhaust air channel of an equipment cabinet or as fan modules in a cooling unit of a cabinet arrangement are regulated.

According to the basic measurement principle the temperature T_{L} of the leakage air flow is determined or influenced by the conveyed air volume and the flow direction. If too little air is conveyed the ventilators of the electronic module units or servers draw air into the cooling air channel from the hot exhaust air region, which leads to a temperature increase and causes the rotation speeds of the fans to be increased in the exhaust air region. The reference variable for the speed regulation of the fans is the temperature T_{L} of the leakage air flow which is determined by the flow direction and thus by the air volume flow made available in the cooling air channel. Through the regulation of the fan rotation speeds the volume flow of the cooling air is adapted to the volume flow actually required by the servers.

The inventive method and the inventive sensor arrangement can advantageously be used in an equipment cabinet which is described in EP 1 614 333 B1. In such an equipment cabinet a leakage air flow can usefully be formed through an opening in a separating wall in the region of the cooling air channel and be provided with a temperature sensor.

In a cabinet arrangement with equipment cabinets which are arranged in particular in a row and wherein a cooling unit is arranged with a heat exchanger and fans laterally abutting an equipment cabinet or between two equipment cabinets, whereby the fans are received in fan modules and a cold air channel for the cold air cooled in the heat exchanger and leaving with orientation by means of the fan modules is formed on the front side of the cooling unit and on the rear side thereof a hot air channel for the hot air from one or two equipment cabinets impacted with the heat loss is formed, the inventive method and the inventive sensor arrangement can likewise be advantageously used. At least one leakage air flow can thereby be formed using an opening in a separating wall between the cold air channel and the hot air channel and be provided with a temperature sensor. A particularly advantageous regulation is achieved if a leakage air flow is provided for each fan module. Regarding the arrangement of equipment cabinets and at least one cooling unit which comprises a heat exchanger and fans in insertable fan modules, reference is made to the German patent application No. 10 2007 061 966.0 and the parallel international patent application PCT/EP 2008/008908, the content of which is hereby incorporated into this application.

The positioning of the purposefully incorporated opening for the leakage air flow above the uppermost server is advantageous, whereby the opening is usefully dimensioned so that it is as small as possible but at the same time is large enough so that a quantity of air cannot accumulate above the uppermost server, in particular so that no hot air pool can form.

In principle the diameter of the opening is dependent upon the size of the cabinet and the module unit arranged and operated therein.

It has been found that the diameter of the opening for a leakage air flow can lie in a range of from approximately 5 to 15 mm and can be for example 8, 9, 10, 11, 12, 13 mm. Moreover the diameter can be determined through few trials and it is also possible to vary the diameter on site, corresponding to the regulation of a cabinet and the heat which has developed, for example to provide different tubes, pipes or for a regulatable opening plug-in or slide-in elements for diameter variation.

In the inventive regulating concept for an equipment cabinet it is advantageous that simultaneously the cooling air inlet temperature into the cooling air channel arranged in particular on the front side can be regulated via the water through-flow of the heat exchanger.

It can also prove useful for a second temperature sensor to also regulate the supply temperature of the cooling fluid of the air/fluid heat exchanger in the bottom region of the cooling air channel and close to the air/fluid heat exchanger.

In principle the through-flow quantity regulation and/or regulation of the supply temperature of the cooling fluid can also take place with the aid of the temperature sensor in the leakage air flow. If a temperature sensor is arranged in the leakage air flow in the upper region of the equipment cabinet or the cooling air channel and a second temperature sensor is arranged in the bottom region close to the heat exchanger it is useful to avoid a mutual influencing of the regulating circuits and to consider that after the exit from the heat exchanger the cooling air heats up slightly. It is therefore useful to set the temperature reference value of the sensor in the leakage air flow for the regulation of the fans in the exhaust air region to be higher than the reference value on the second temperature sensor.

The leakage air flow for a temperature sensor arranged therein can advantageously also be formed with the aid of a pipe or a tube. The pipe or tube must then be laid between the cooling air channel and the exhaust air region or channel. The pipe or tube can advantageously be laid in different position variants and the leakage air can then be removed from preferred cabinet regions and the temperature of this leakage air measured and the corresponding signal used to regulate the fans.

It can also prove useful to form more than one leakage air flow in an equipment cabinet and to respectively arrange a temperature sensor in the opening and/or in a pipe and/or in a tube for the respective leakage air flow. The arrangement of temperature sensors in a plurality of leakage air flows can additionally advantageously be used for individual regulation of individual fans or ventilators.

In the positioning, occupancy with electronic module units or servers with particularly high heat loss can be considered and this has an advantageous effect upon the energy balance for cooling the whole arrangement.

The advantages of the inventive regulating method and the sensor arrangement comprise a considerable energy saving due to an extensively adapted required air quantity in a cabinet or computer centre. The use of cooling air can be decreased and the space in a computer centre or server room can be optimally utilised. Besides the lower energy costs for driving the fans the appropriate supply air temperature for the servers is ensured. All in all a particularly energy efficient cooling can be achieved.

The invention is explained in further detail below by reference to a highly schematised drawing, in which:

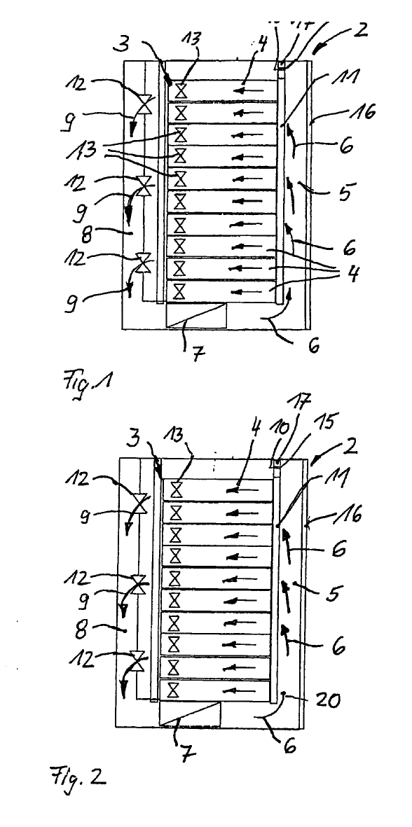

FIG. 1 shows a longitudinal section through an equipment cabinet with the inventive sensor arrangement;

FIG. 2 shows a longitudinal section through the cabinet according to FIG. 1 with an alternative sensor arrangement;

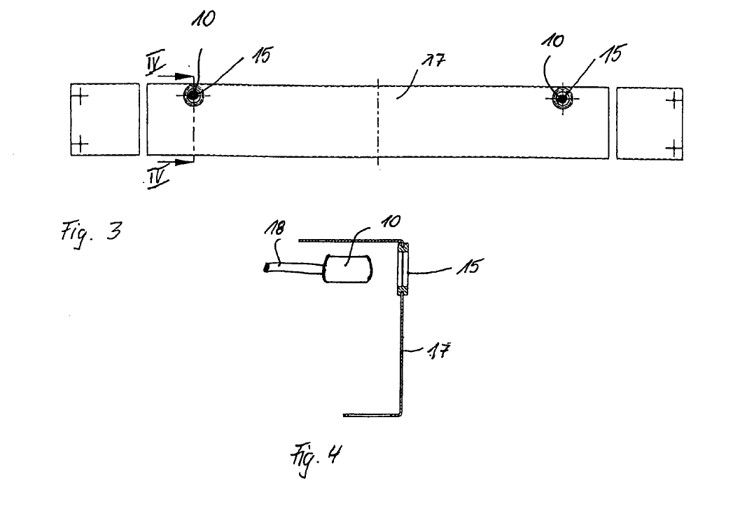

FIG. 3 shows an enlarged view according to arrow III in FIG. 1 and

FIG. 4 shows a longitudinal section according to line IV-IV in FIG. 3.

FIG. 1 shows an equipment cabinet 2 with a receiving area 3 and electronic module units 4 arranged one on top of the other. The equipment cabinet 2 is a server cabinet in this embodiment and the electronic module units 4 can be for example high power servers of a rack unit. The air conveyance in the region of the servers 4 is indicated by arrows. Within each of the housings of the servers 4 a ventilator 13 is arranged, which manages the air conveyance through the servers 13 and draws in cooling air 6 by means of front side air inlet openings (not shown), conveys it via the electronic components generating heat loss (not shown) and supplies it via rear side air outlet openings (not shown) to an exhaust air channel 8.

An air/fluid heat exchanger 7 is arranged below the receiving area 3, said air/fluid heat exchanger 7 being an air/water heat exchanger here and being connected to the cold water supply of the building.

The air cooled in the air/fluid heat exchanger 7 is fed as cooling air 6 to a cooling air channel 5 which is arranged on the front side, extends over virtually the whole height of the equipment cabinet 2 and is connected to the air inlet openings (not shown) of the servers 4. The exhaust air 9 heated by the servers 4 is conveyed via a rear side exhaust air channel 8 with the aid of fans 12 in this exhaust air channel 8 into the heat exchanger 7.

The air-related separation of the supplied cooling air 6 from the heated exhaust air 9 takes place in the front side region of the receiving area with the aid of separating walls 11 which can be for example angled metal plates and are arranged vertically so that the separating walls 11, a front door 16 and the housing front sides of the servers 4 delimit the cooling air channel 5 together with upper and lower covers of the cabinet 2.

In order to regulate the closed cooling air circuit in the equipment cabinet 2 according to FIG. 1 with adaptation of the necessary cooling air quantity to be circulated to the volume flow conveyed by the ventilators 13 of the individual servers 4 the temperature of the cooling air which is fed to the servers 4 is measured in a leakage air flow. The leakage air flow is formed in the embodiment according to FIG. 1 in the region of an upper separating wall 17 above the uppermost server 4 and connects the cooling air channel 5 to the exhaust air channel 8 or the exhaust air region on the other side of the cooling air channel 5.

The leakage air flow which is purposefully dimensioned is formed in FIG. 1 through an opening 15 in the upper separating wall 17, whereby the opening 15 is dimensioned so that it is relatively small but at the same time is sufficiently large so that a hot air pool cannot form in the upper region of the cooling air channel 5.

A hot air pool in the upper region of the cooling air channel 5 or a hot air layer can arise if the heat loss developed by the servers 4 or other structural elements in the receiving area 3 is particularly large and is transferred via the metal housing to the cooling air in the cooling air channel 5. In order to prevent the hot air pool from reaching the region of the servers 4 the opening 15 is correspondingly dimensioned for a leakage air flow so that the hot air pool is removed in the upper region into the exhaust air channel 8 and cannot be drawn in by the ventilators 13 of the servers 4.

An essential feature is the strict separation of the cold air region or the cooling air channel 5 from the exhaust air region or exhaust air channel 8 through the separating walls 11 on both sides of the server front sides and through separating elements, for example blind plates (not shown), at positions remaining free between the servers 4 arranged one on top of the other and/or one beside the other. If necessary a leakage air flow to be detected can also be formed in the blind plates for cooling air regulation.

In order to make an air quantity available to the servers 4 which corresponds to the required cooling air quantity of the servers 4 or is orientated to the power of the ventilators 13 of the servers 4, the leakage air flow is detected in the region of the opening 15 in that a temperature sensor 10 is incorporated and used to regulate the fans 12 in the rear side exhaust air channel 8. The temperature sensor 10 can be inserted into the opening 15 so that it can be ascertained by means of the temperature measurement whether too much air or too little air is conveyed into the cooling air channel 5 and made available for the servers 4. If too little air is conveyed, the servers 4 draw the heated exhaust air 9 from the exhaust air region or exhaust air channel 5 into the cooling air channel 5 so that the rotation speed of the fans 12 increases in the exhaust air channel 8 and vice versa.

In place of an opening 15 a pipe or a tube (not shown) can also be arranged in the region of the air separation or the separating walls 11 or blind plates (not shown) for a temperature sensor 10 of a leakage air flow. The temperature T_{L} of the leakage air flow is used for speed regulation of the fans 12 in the region of the exhaust air channel 8 and thus forms the reference variable for the rotation speed regulation of the fans 12.

FIG. 2 shows an alternative sensor arrangement with a temperature sensor 10 in the upper region of the equipment cabinet 2 which corresponds essentially to the equipment cabinet 2 of FIG. 1. The same features are provided with identical reference numerals. An additional, second temperature sensor 20 is arranged in the cooling air channel 8 and close to the air/fluid heat exchanger 7. The temperature sensor 10 in the leakage air flow serves in turn to regulate the fans 12 in the region of the exhaust air channel 8 while the through-flow quantity and/or supply temperature of the cooling fluid of the air/fluid heat exchanger 7 can be regulated with the second temperature sensor 20.

FIGS. 3 and 4 show an upper separating wall 17 of the cooling air channel 5 according to FIGS. 1 and 2, here with two openings 15 respectively for a leakage air flow and the incorporation of a temperature sensor 10 with cable 18.

In this embodiment the two openings 15 are formed identically, being round and having a diameter of approximately 10 mm.

The cross-section can advantageously also be selected to be square or rectangular and the cross-section of an opening or the sum of the cross-sections of a plurality of openings in a cooling air channel can be adapted to the respective conditions such as cabinet dimensions, particularly the volume of the cooling air channel, the occupancy of the receiving area and the heat development of the module units and also the speed-regulated fans.

1-10. (canceled)

11. A method for regulating the cooling air in equipment cabinets of computer rooms,
wherein cooling air is fed to electronic module units arranged in the equipment cabinets and exhaust air impacted with the heat loss of the electronic module units is cooled in an air/fluid heat exchanger,
wherein the cooling air is fed via a cooling air channel arranged on the front side with the aid of fans in an exhaust air channel arranged on the rear side to the electronic module units via front side openings and the heated exhaust air is fed via rear side air outlet openings of the electronic module units to the exhaust air channel and thereafter to the air/fluid heat exchanger arranged on the bottom side, in which the heat loss is taken up by a cooling fluid and given off outside of the computer room, and
wherein separating walls are arranged in the region of the cooling air channel for air-related separation of the cooling air from the exhaust air and a leakage air flow is conveyed through a purposefully incorporated opening in an upper separating wall above the uppermost electronic module unit and between the cooling air channel and the exhaust air channel and wherein the required cooling air quantity of the closed cooling air circuit is conveyed via the rotation speed regulation of fans in dependence upon the temperature of the cooling air,
wherein the required cooling air quantity is adapted to the volume flow conveyed by ventilators in the electronic module units and the temperature in the leakage air flow between the cooling air channel and the exhaust air channel is measured and used as a reference variable for the speed regulation of the fans, and in that a temperature sensor is arranged in the purposefully incorporated opening in the upper separating wall and the temperature T_{L} of the leakage air flow which is determined by the flow direction of the leakage air flow and thus by the air volume flow made available in the cooling air channel is measured and used for rotation speed regulation of the fans in the exhaust air channel,
wherein in case of a temperature increase in the leakage air flow the rotation speed of the fans is increased and in case of a temperature reduction the rotation speed of the fans is reduced and the volume flow of the cooling air is thus adapted to the volume flow actually required by the module units.

12. The method according to claim 11, wherein the purposefully incorporated opening is dimensioned for a leakage air flow between the cooling air channel and the exhaust air channel in such a way that an air quantity which has accumulated above the uppermost electronic module unit in the cooling air channel, in particular a hot air pool which has formed through transmission of the heat loss via the metal housing to the cooling air in the cooling air channel, is avoided or continuously carried away.

13. The method according to claim 11, wherein the through-flow quantity and/or the supply temperature of the cooling fluid of the air/fluid heat exchanger is regulated using the temperature sensor in the purposefully incorporated opening.

14. The method according to claim 11, wherein using a second temperature sensor which is arranged in the cooling air channel close to the air/fluid heat exchanger, the temperature in the cooling air is measured and used to regulate the through-flow quantity and/or the supply temperature of the air/fluid heat exchanger.

15. The method according to claim 14, wherein the temperature reference value of the temperature sensor is set in the leakage air flow for the rotation speed regulation of the fans in the region of the exhaust air channel to be higher than the temperature reference value of the second temperature sensor close to the air/fluid heat exchanger for the regulation of the through-flow quantity and/or supply temperature of the cooling fluid of the air/fluid heat exchanger.

16. The method according to claim 11, wherein the leakage air flow is conveyed in a pipe or in a tube which is arranged between the cooling air channel and the exhaust air channel.

17. The method according to claim 11, wherein more than one leakage air flow is formed in an equipment cabinet and a respective temperature sensor is arranged in the opening or in the pipe or in the tube for the leakage air flow.

18. The method according to claim 11, wherein the leakage air flows are formed in dependence upon the occupancy of the equipment cabinet with electronic module units and the heat loss thereof and are provided with temperature sensors for regulating the fans.

19. The sensor arrangement for regulating the cooling air in equipment cabinets of computer rooms which comprise a receiving area for electronic module units, in particular high power servers, a cooling air channel arranged on the front side for feeding cooling air from an air/fluid heat exchanger arranged on the bottom side to the electronic module units and an exhaust air channel arranged on the rear side, from which the exhaust air of the electronic module units impacted with the heat loss can be fed to the air/fluid heat exchanger,
wherein the cooling air channel is separated in terms of air from the exhaust air channel by separating walls, an opening is formed in an upper separating wall above the uppermost electronic module unit for a leakage air flow between the cooling air channel and the exhaust air channel and speed-regulated fans are arranged in the exhaust air channel and beside the ventilators in the electronic module units convey the air in a closed circuit, in particular for implementing the method according to claim 11,
wherein a temperature sensor is arranged in the region of the leakage air flow and the temperature T_{L} of the leakage air flow which is determined by the flow direction of the leakage air flow and thus by the air volume flow made available in the cooling air channel is the reference variable for the rotation speed regulation of the fans,
wherein in case of a temperature increase of the leakage air flow the speed of the fans is increased and in case of a temperature reduction in the leakage air flow the speed of the fans is reduced and the volume flow of the cooling air is thus adapted to the volume flow actually required by the module units.
